(19) United States
(12) Patent Application Publication
(10) Pub. No.: US 2012/0038175 A1
(43) Pub. Date: Feb. 16, 2012

(54) GENERATING AND USING ELECTRICITY DERIVED FROM WASTE HEAT OF AN ELECTRICAL APPLIANCE

(76) Inventors: William S. Tang, Orinda, CA (US); Yancy Chen, Campbell, CA (US)

(21) Appl. No.: 13/264,744

(22) PCT Filed: Apr. 15, 2009
(86) PCT No.: PCT/US09/40632

§ 371 Date: Oct. 14, 2011

(51) Int. Cl. H02K 7/18; H01L 35/30

(52) U.S. Cl. 290/1 R; 136/205

(57) ABSTRACT

A system 101A, 101B for deriving operating electricity for an electrical appliance 100A, 100B from wasted heat of the electrical appliance 100A, 100B comprises a heat generating component 110 of the electrical appliance 100A, 100B, a thermoelectric device 120 thermally coupled with the heat generating component 110, a charge storage device 140 electrically coupled with the thermoelectric device 120, and a real-time parasitic component 157 of electrical appliance 100A, 100B that is electrically coupled with thermoelectric device 120 and charge storage device 140. Thermoelectric device 120 is configured to thermoelectrically generate electricity from waste heat of heat generating component 110. The waste heat is generated by heat generating component 110 during operation of electrical appliance 100A, 100B. Real-time parasitic component 157 is configured to receive a portion of its real-time operating electricity from thermoelectric device 120 and a portion of its parasitic operating electricity from charge storage device 140.

### BACKGROUND

Electrical appliances such as, for example, personal computers and laser printers among others, use considerable electricity. Consider the example of a typical home personal computer that, while idling, may utilize the electrical equivalent of the energy needed to run three or more light bulbs in a household. Moreover, in addition to electrical use during operation, many electrical appliances that are plugged into wall outlets continue to parasitically consume small amounts of electricity even when in a seemingly powered down or “off” state. Thus, in a household, or collectively across a business or an entity such as a government agency, electrical appliances consume very large amounts of electricity while operating, while idling, and even while seemingly powered down.

### BRIEF DESCRIPTION OF THE DRAWINGS

The accompanying drawings, which are incorporated in and form a part of this specification, illustrate various embodiments of the present invention and, together with the description of embodiments, serve to explain principles discussed below.

FIG. 1A is a diagram of an example electrical appliance that generates and uses electricity derived from waste heat of the electrical appliance, in accordance with various embodiments.

FIG. 1B is another diagram of an example electrical appliance that generates and uses electricity derived from waste heat of the electrical appliance, in accordance with an embodiment.

FIG. 2 is a flow diagram of a method of recycling waste heat of an electrical appliance into operating electricity for the electrical appliance, according to one embodiment.

FIG. 3 is a flow diagram of a method for providing a computing appliance, according to one embodiment.

The drawings referred to in this brief description of the drawings should not be understood as being drawn to scale unless specifically noted.

### DESCRIPTION OF EMBODIMENTS

Reference will now be made in detail to various embodiments of the subject matter, examples of which are illustrated in the accompanying drawings. While various embodiments are discussed herein, it will be understood that they are not intended to omit to these embodiments. On the contrary, the presented embodiments are intended to cover alternatives, modifications and equivalents, which may be included within the spirit and scope the various embodiments as defined by the appended claims. Furthermore, in this Description of Embodiments, numerous specific details are set forth in order to provide a thorough understanding of embodiments of the present subject matter. However, embodiments may be practiced without these specific details. In other instances, well known methods, procedures, components, and circuits have not been described in detail as not to unnecessarily obscure aspects of the described embodiments.

### OVERVIEW OF DISCUSSION

As described herein, wasted heat of an electrical appliance, such as a computing device, is captured and used to generate electricity for operating one or more components of the electrical appliance. The components may be real-time components, parasitic components, real-time parasitic components, or a combination thereof. As will be described, in various embodiments, the electricity is generated by one or more thermoelectric device(s) operated by waste heat of one or more components of the electrical appliance, by one or more microturbines operated by waste heat of one or more components that is harnessed to spin the microturbine(s), or by some combination of one or more thermoelectric devices and one or more microturbines.

Discussion will begin with a description of an example electrical appliance equipped with electricity generating components that operate from waste heat of the electrical appliance. Aspects of the electrical appliance and its power generation components will be described. A description of various components powered by the waste heat power generating component(s) and/or stored electricity generated by such waste heat power generating component(s) will be given. Provision of and operation of the electrical appliance and its waste heat power generating components will then be described in more derail in conjunction with a description of an example a method of recycling waste heat of an electrical appliance into operating electricity for the electrical appliance and also in conjunction with a method for providing a computing appliance.

### Example Appliance and System for Generating and Using Electricity Derived From Wasted Heat of the Electrical Appliance

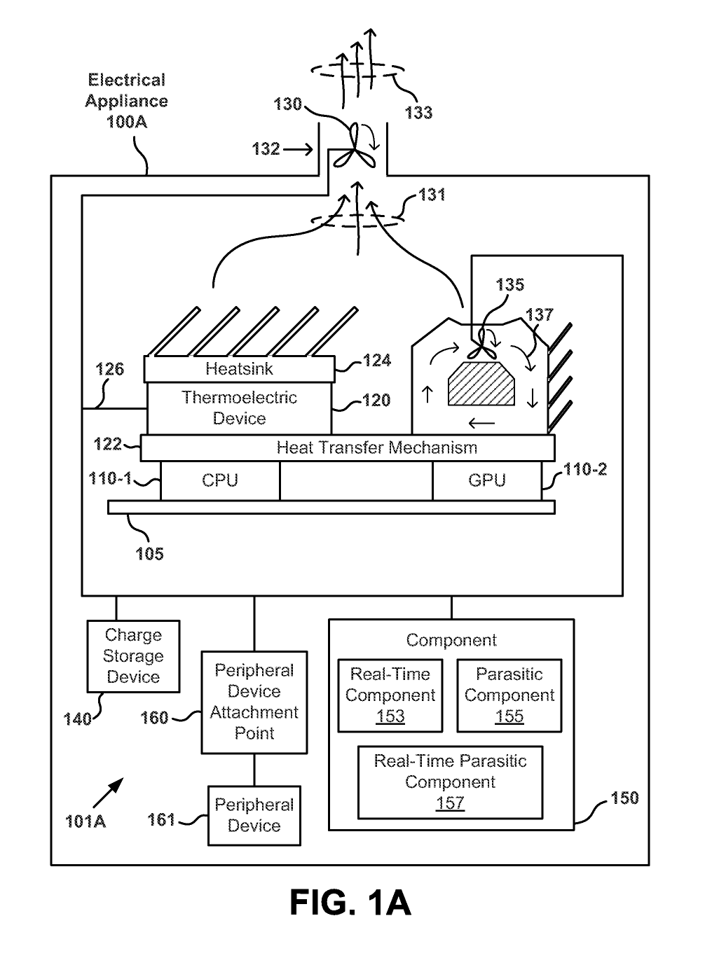

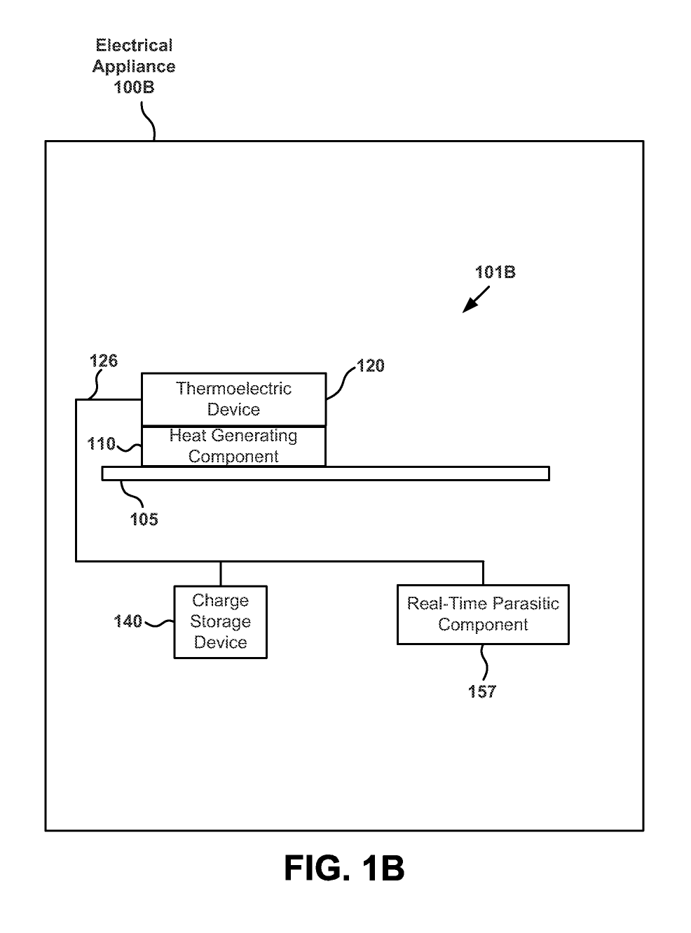

FIG. 1A is a diagram of an example electrical appliance 100A that generates and uses electricity derived from waste heat of the electrical appliance 100A, in accordance with various embodiments. In one embodiment, electrical appliance 100A is a computing appliance, such as a wall plugged (e.g. plugged into alternating current such as 110/120 volt AC) personal computer, laser printer, media device, or the like. It is appreciated that a plurality of the components illustrated with electrical appliance 100A form various embodiments of a system 101A for deriving operating electricity for an electrical appliance from wasted heat generated as a by-product of the operation of the electrical appliance. It is also appreciated that the principles illustrated with electrical appliance 100A and the waste heat generation system 101A thereof are extensible to a wide variety of electrical appliances that include heat generating components, such as solid state components, processors, and amplifiers, among others, that generate waste heat as a by-product of their operation to perform other purposes (such as amplification of a signal, voltage regulation, or processing).

As shown in FIG. 1A, electrical appliance 100A includes a circuit board 105, which may comprise a motherboard in one embodiment, or can represent a collection of circuit boards. Upon circuit board 105 (or a plurality of circuit boards) of electrical appliance 100A, one or more heat generating components 110 are mounted. These heat generating components 110 generate heat as a by-product of their operation. As represented in FIG. 1A, such heat generating components 110 can include a central processing unit 110-1 and a graphics processing unit 110-2, among others. In some embodiments, such heat generating components 110 can include solid state components such as amplifiers, voltage regulators, or components such as resistors, transformers, or hard disk drives. The heat generated by heat generating component(s) 110 is used in one or more of the manners described herein to generate electricity that can be used in or by electrical appliance 100A, thus reducing the overall amount of electricity drawn from a wall outlet. While embodiments are described with reference to heat generating components 110, it is appreciated that an electrical appliance 100A may also include other components, such as transformers, voltage regulator, or resistors, among others, that generate heat as a by-product of their operation, and which can additionally or alternatively be utilized for electricity generation in the processes described herein.

As shown in FIG. 1A, in one embodiment, a thermoelectric device 120 is thermally coupled with at least one heat generating component, such as central processing unit 110-1. In one embodiment, thermoelectric device 120 comprises a Peltier junction device. In one embodiment, thermoelectric device 120 comprises a solid state device that generates electricity when a suitable temperature differential is created across the thermoelectric device 120. In one embodiment, the electricity generated by thermoelectric device 120 is output on electrical bus 126. The thermal coupling of thermoelectric device 120 with a heat generating component 110 can comprise coupling thermoelectric device 120 directly with one or more heat generating components 110 with no intervening mechanism between the two (other than perhaps a minimal layer of thermal grease or adhesive). This coupling can also comprise indirectly thermally coupling thermoelectric device 120 with one or more heat generating components 110.

In one embodiment, an indirect thermal coupling can comprise a structure such as a heat transfer mechanism 122 that is disposed between, and thermally coupled with, thermoelectric device 120 and also with one or more heat generating components 110 that generate waste heat. Heat transfer mechanism 122 assists in transferring heat from one location to another. This can allow thermoelectric device 120 to be positioned at a remote location (i.e., not directly atop) from a heat generating component 110. This can also allow the waste heat from a plurality of heat generating components 110 to be collected and aggregated. Various types of structures can be employed as heat transfer mechanism 122. Some non-limiting examples include sheets or bars of metal, such as copper or aluminum, and mechanisms such as heat pipes that may include an internal fluid. In one embodiment, heat transfer mechanism 122 of FIG. 1A, comprises a flat heat pipe that collects heat from a plurality of heat generating components 110 and transfers the heat to thermoelectric device 120. As heat generating components 110, such as processors, often operate at temperatures in the vicinity of 100 degrees Celsius while simply idling, it can be seen that a substantial amount of energy in the form of wasted heat is available for transfer to thermoelectric device 120.

The transfer of such wasted heat assists in creating an appropriate temperature differential across thermoelectric device 120 (a hotter side near heat generating component(s) 110 and a cooler side further from heat generating component(s) 110) using the waste heat from heat generating component(s) 110. This temperature differential allows thermoelectric device 120 to generate electricity during the operation of electrical appliance 100A and heat generating component(s) 110. In one embodiment, the electrical power generated by thermoelectric device 120 is in the range of several millivolts, but may be more or less in other embodiments. In one embodiment, a cooling device, such as heat sink 124, is disposed on a surface of thermoelectric device 120 that is opposite from the heated surface of thermoelectric device 120. Use of heat sink 124 or another cooling device or technique helps dissipate heat from this opposing side and thereby creates a more pronounced temperature differential across thermoelectric device 120.

In one embodiment, electricity generated by thermoelectric device 120 is electrically coupled, via electrical bus 126, to a component 150 of electrical appliance 100A. What is meant by “component” is any component of electrical appliance that uses thermally generated electricity in real-time as it is being generated within electrical appliance 100A, uses stored electricity generated in such a manner, or uses some combination of stored electricity and real-time electricity. In this manner, the generated electricity provides all or part of the operating electricity for the component. Even providing only a portion of the electrical need of a component 150 will defray the amount of electricity received from a wall socket by electrical appliance 100A. Some examples of components 150 include, but are not limited to, a clock, a fan, a motor (such as the motor used for extending/retracting the media tray of a compact disk/digital versatile disk drive), an indicator light (e.g., a light emitting diode), a liquid crystal display, a power switch for powering electrical appliance 100A on and off, and/or an integrated circuit.

Components 150 include at least three classes: real-time components 153; parasitic components 155; and real-time parasitic components 157. A real-time component 153 is only active when electrical appliance 100A is in a powered on state, and uses electricity thermally generated within electrical appliance 100A in real-time, as it is produced, to provide some or all of the operating electricity for the real-time component 153. Some non-limiting examples of a real-time component 153 include a liquid crystal display, a status indicator light, or a motor. A parasitic component 155 is only active and consuming stored electricity that has been thermally generated within electrical appliance 100A at a time when electrical appliance 100A is in a powered down or “off” state. One example of such a parasitic component 155 is a light that illuminates a power switch of electrical appliance 100A, when electrical appliance 100A is in a powered down or off state, such that a user can readily find the power switch in a darkened environment. A real-time parasitic component 157 is something of a combination of a real-time component 153 and a parasitic component 155 in that it uses electricity thermally generated within electrical appliance 100A in real-time when electrical appliance 100A is in a powered on state and uses stored electricity that has been thermally generated within electrical appliance 100A when electrical appliance 100A is in a powered down or off state. One example of real-time parasitic component 157 is a power switch that constantly draws a small amount of electricity so that a notification can be provided to a motherboard when the power switch is moved from an OFF position to an ON position or from an ON position to an OFF position. This small amount of electricity is consumed by a real-time parasitic power switch whether electrical appliance 100A is in an on state or an off state. It is appreciated that the term “parasitic” is a reference to an electrical draw of a component (155, 157) that would typically constitute a small electrical draw from the grid (or grid supplied stored electricity) in a conventional electrical appliance.

In one embodiment, electricity generated by thermoelectric device 120 is electrically coupled, via electrical bus 126, to a peripheral device attachment point 160 of electrical appliance 100A. What is meant by “peripheral device attachment point” is a connection such as a power outlet or bus (e.g., a Universal Serial Bus) to which a peripheral device 161 can be coupled for receiving all or a portion of its operating electricity. Peripheral devices are differentiated from real-time components in that they are external to electrical appliance 100A. Even providing only a portion of the electrical need of a peripheral device 161 will defray the amount of electricity received from a wall socket by electrical appliance 100A for powering a peripheral device 161. Some non-limiting examples of peripheral devices 161 include, but are not limited to, lights, pointers (e.g., a mouse), keyboards, and thumb drives.

In one embodiment, electricity generated by thermoelectric device 120 is electrically coupled, via electrical bus 126, to a charge storage device 140. In various embodiments, charge storage device 140 comprises a rechargeable battery, a capacitor, or a combination of one or more batteries and one or more capacitors. Charge storage device 140 stores some portion of the electricity produced by thermoelectric device 120 so that it can be used at a later time when real-time power is not available and/or to provide surges of power which would exceed the real-time generating capacity of thermoelectric device 120.

Some examples of a later time use include providing electricity stored in charge storage device 140 for use by a parasitic component 155 and/or a real-time parasitic component 157 at a time when real-time electricity produced by thermoelectric device 120 is not available. Consider an embodiment where electrical appliance 100A comprises a wall plugged computing appliance and where real-time parasitic component 157 comprises a power switch that constantly draws a small amount of electricity so that a notification can be provided to the motherboard when the power switch is moved from an OFF position to an ON position or from an ON position to an OFF position. When the computing appliance is in a powered on state, this power switch acts like a real-time component. All or a portion of the real-time electricity needs of this power switch can be provided by electricity generated in real-time by thermoelectric device 120. However, this electricity requirement and power draw continues in a parasitic fashion even when the computing device is seemingly in a powered off state and thermoelectric power generation is not taking place. Such a parasitic power draw may be small for any single electrical appliance, but adds up when viewed across the electrical appliances of a building, business, government, or other entity. According to one embodiment, all or a portion of the electricity for such a power switch's parasitic electricity need is provided from charge storage device 140, thus defraying or eliminating what would otherwise be a parasitic electricity draw from the wall outlet/grid by the computing appliance. In this manner, charge storage device 140 continues to supply the electric needs from the stored thermally generated electricity even when real-time electricity generation has ceased and even when the computing appliance is in a powered off state.

Consider another embodiment where the real-time parasitic component 157 comprises a clock of electrical appliance 100A. In another example of later use, in one embodiment, electricity that is thermally generated within electrical appliance 100A is provided to operate the clock or for charging the power source for the clock. Thus, when electrical appliance 100A is thermally generating electricity in real-time, all or a portion of the real-time electrical needs of the clock are provided by the real-time power that is generated. Similarly, when electrical appliance is powered down and in a state where real-time thermal electricity generation is not taking place, all or a portion of the parasitic electricity needs of the clock are provided by charge storage device 140.

Some examples of a surge use include situations when charge storage device 140 provides all or part of the power for an electric motor, such as supplementing startup electricity needed for starting a fan or providing the electricity needed to operate a motor to open or dose a media receiving tray, such as a disk receiving tray of a compact disk and/or digital versatile disk drive. Often such surge electrical needs will exceed the real-time electricity being generated within electrical appliance 100A, and can be provided for (at least in part) by charge storage device 140.

it is appreciated that in some embodiments, electrical appliance 100A utilizes or additionally includes one or more microturbines (130, 135) to generate electricity from waste heat of its heat generating component(s) 110. In one embodiment, in addition to thermoelectric device 120, one or more microturbines (130,135) generate additional electricity that can be stored in a charge storage device 140, coupled to a component 150, and/or coupled to a peripheral device attachment point 160 for powering a peripheral device 161. A microturbine (130, 135) is coupled with electrical appliance 100A and operates to generate electricity from heat radiated from operation of electrical appliance 100A (e.g., waste heat from one or more heat generating components 110). In one embodiment, this comprises using fluid movement, that is induced by convection, to turn the microturbine(s) and generate electricity.

Microturbine 130 illustrates electrical generation from movement of a convectively heated fluid (in the form of rising currents of hot air). Lines 131 show convection currents rising from heat generating component(s) 110 to outlet 132 and turning microturbine 130 as they are exhausted from electrical appliance 100A as shown by lines 133. Electricity generated by microturbine 130 is electrically coupled to electrical bus 126, or a similar electrical conduit, in the same fashion as electricity generated by thermoelectric device 120.

Microturbine 135 illustrates electrical generation from movement of a fluid (in the form of a circulating cooling liquid). This cooling liquid may be circulated by a powered circulation (such as with a pump) or a convective circulation. For example, the convective circulation may be driven by heat absorbed by the cooling liquid from heat transfer mechanism 122 (or directly from a heat generating component 110 if an intervening heat transfer mechanism 122 is not employed) and then expelled (such as by cooling fins of a heat sink) as the cooling liquid is cooled during the circulation. It is appreciated that liquid cooling of heat generating components 110 such as central processing unit 110-1 and graphics processing unit 110-2 is known, and is modified herein such that a microturbine 135 is included to generate electricity from the recirculating flow of the cooling liquid. Electricity generated by microturbine 135 is electrically coupled to electrical bus 126, or a similar electrical conduit, in the same fashion as electricity generated by thermoelectric device 120.

Though the concepts for generating electricity from waste heat are illustrated with respect to a single electrical appliance, it should be appreciated that they can be scaled for use with a plurality of electrical appliances, such as a rack of computers or other electrical appliances e.g., a rack of server computers) and/or to a room or building of such electrical appliances or racks of electrical appliances (e.g., a server room or a server farm). For example, hot exhaust air from a rack, room, or building, can be used to turn one or more microturbines and generate electricity in conjunction with electricity produced by a plurality of thermoelectric devices that are generating electricity at a component or electrical appliance level within the racks, rooms, or buildings.

As can be seen, system 101A that derives electricity from waste heat of an electrical appliance (e.g., 100A, among others) comprises thermoelectric device 120 and electrical bus 126. As can be seen electrical bus 126 may be coupled with charge storage device 140 and with one or more components 150 and/or one or more peripheral device attachment points 160. The generated electricity can be provided for use by the electrical appliance whose components generate the waste heat used for deriving the electricity. With continued reference to FIG. 1A, it is appreciated that in various embodiments system 101A can include one or more of additional components, such as, but not limited to: heat transfer mechanism 122, heatsink 124, microturbine 130, and microturbine 135.

FIG. 1B is another diagram of an example electrical appliance 166E that generates and uses electricity derived from waste heat of the electrical appliance 100B, in accordance with an embodiment. In FIG. 1B, like designation numbers represent the same components/structures as those designation numbers of FIG. 1A. As shown in FIG. 1B, not all of the components illustrated in FIG. 1A are utilized in every embodiment, in order to capture waste heat of one or more heat generating components 110 and convert the waste heat into electricity for use by the electrical appliance 100B. As but one non-limiting example, FIG. 1B is shown with thermoelectric device 120 being used to generate electricity from a heat generating component 110 and then electrically couple that electricity to a real-time parasitic component 157 (for providing all or part of the real-time electricity needs) and/or to charge storage device 140 (for surge supplementation use or for use by real-time parasitic component 157 at a later time when thermally generated electricity is not being generated within electrical appliance 100B). It is appreciated that heat generating component 110 can in various embodiments, be a processor, amplifier, voltage regulator, or other solid state or non-solid state component (e.g., a hard disk drive), that generates heat as a by-product of its operation.

As can be seen, a system 101B that derives electricity from waste heat of an electrical appliance (e.g., 100A, 100B, among others) comprises thermoelectric device 120 and electrical bus 126. As can also be seen, electrical bus 126 may be coupled with charge storage device 140 and also with one or more real-time parasitic components 157. In this manner, the generated electricity can be provided for use by a variety of components 150 of electrical appliance 100B whose heat generating component(s) generate the waste heat from which the thermally generated electricity is derived.

### Example Method of Recycling Waste Heat of an Electrical Appliance into Operating Electricity for the Electrical Appliance

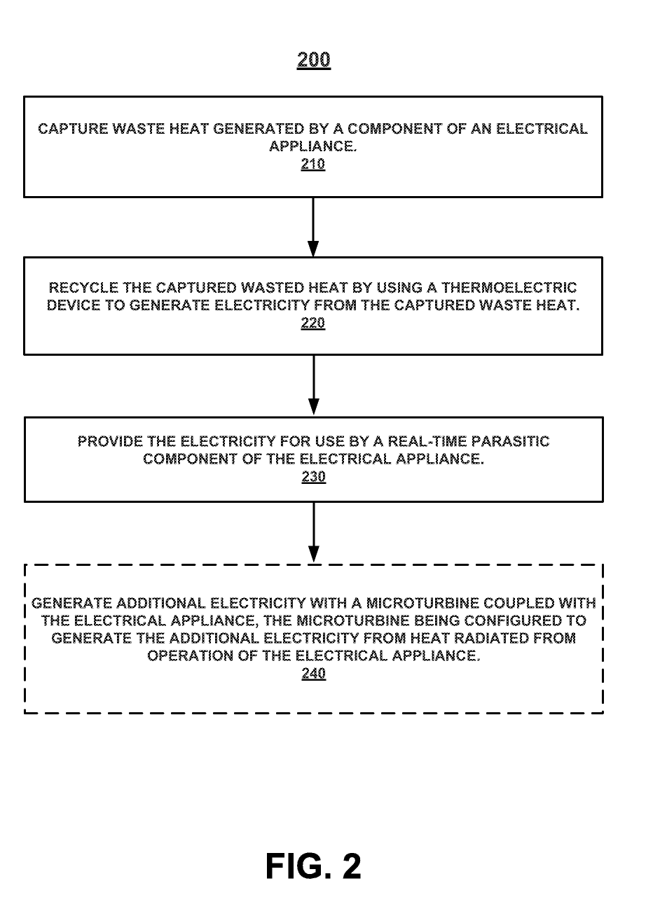

FIG. 2 illustrates a flow diagram 200 of an example embodiment of a method of recycling waste heat of an electrical appliance into operating electricity for the electrical appliance. Elements of flow diagram 200 are described below, with reference to elements of FIG. 1A and FIG. 1B.

At 210 of flow diagram 200, in one embodiment, the method captures waste heat generated by a component of the electrical appliance. In one embodiment, this is waste heat generated by a component 110, such as a processor or other heat generating component of an electrical appliance (100A, 100B). The capturing can comprise capturing the waste heat in a heated fluid, capturing the waste heat with a heat transfer mechanism 122, and/or capturing the waste heat on a surface of a thermoelectric device 120.

At 220 of flow diagram 200, in one embodiment, the method recycles the captured waste heat by using a thermoelectric device to generate electricity from the captured waste heat. This can comprise transferring captured waste heat to thermoelectric device 120 and using it to create a temperature differential across the thermoelectric device 120 with which to generate electricity.

At 230 of flow diagram 200, in one embodiment, the method provides the generated electricity for use by a real-time parasitic component of the electrical appliance. This can comprise electrically coupling the generated electricity to real-time parasitic component 157 for use in real-time to supply all or a portion of the real-time electricity needs of real-time parasitic component 157. This can also comprise storing a portion of the electricity in a charge storage device 140 for later use to serve all or a portion of the parasitic electricity needs of real-time parasitic component 157 or to supplement surge needs for electricity by real-time parasitic component 157. Real-time parasitic component(s) 157 can be powered all or in part by the electricity as it is generated in real-time and all or in part by stored electricity from charge storage device 140 when thermally generated electricity is not being generated within the electrical appliance. In a similar manner, the electricity generated within electrical appliance can be provided to a real-time component 153 and/or to a parasitic component 155 (see FIG. 1). Likewise the thermally generated electricity can be coupled to a peripheral device attachment point 160 of electrical appliance (see FIG. 1) where it can then be coupled to a peripheral device 161 that is or may be coupled with the peripheral device attachment point 160.

At 240 of flow diagram 200, in one embodiment, the method generates additional electricity with a microturbine coupled with the electrical appliance. In one embodiment, the microturbine generates the additional electricity from heat radiated from operation of the electrical appliance. For example, in one embodiment, fluid movement induced by convection via the waste heat is used to turn the microturbine. In one embodiment, this comprises turning a microturbine (130, 135) with a fluid that has captured waste heat of electrical appliance 100A. This fluid can be a gas, such as air, or a liquid and may be convectively moved/circulated by the waste heat or may be moved to some extent by a powered apparatus such as a cooling fan or a pump. It is appreciated that the electricity generated with one or more microturbines (130, 135) can be stored in charge storage device 140, electrically coupled to a component 150, and/or electrically coupled to a peripheral device attachment point 160 for use by a peripheral device 161.

### Example Method for Providing a Computing Appliance

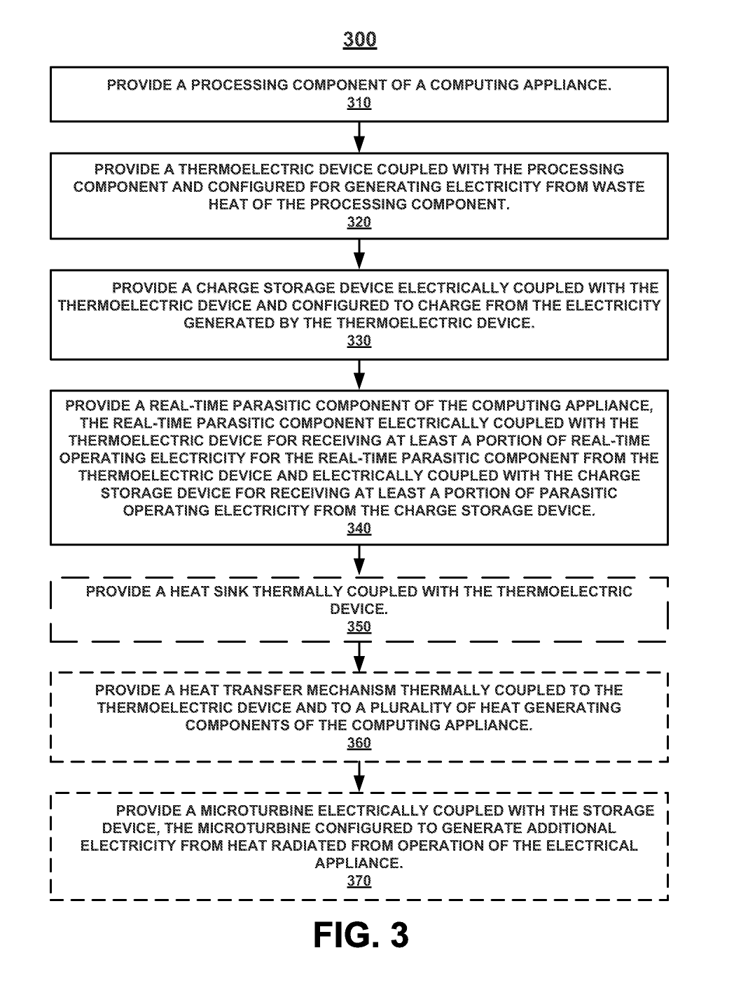

FIG. 3 illustrates a flow diagram 300 of an example embodiment of a method for providing a computing appliance. Elements of flow diagram 300 are described below, with reference to elements of electrical appliance 100A of FIG. 1A and electrical appliance 100B of FIG. 1B. It is appreciated that the “providing” procedures described in flow diagram 300 can comprise manufacturing, selling, and/or or assembling components, sub-components, assemblies, or the entirety of an electrical appliance, such as electrical appliance 100A of FIG. 1A or electrical appliance 100B of FIG. 1B. It is appreciated that in one embodiment, electrical appliance 100A and/or 100B comprises a computing appliance, such as a personal computer, that is or may be connected to grid power (e.g. plugged in to an alternating current outlet such as a 110/120 volt AC outlet). In other embodiments electrical appliance 100A and/or 100B comprises other appliances, such as, but not limited to, a laser printer, a media device such as a digital projector or television, or some other electrical appliance.

At 310 of flow diagram 300, in one embodiment, the method provides a processing component. For example, this can comprise providing one or more processors such as central processing unit 110-1, graphics processing unit 110-2, or other processor(s). The processing component (e.g., 110-1, 100-2, or other processing component) generates waste heat as a by-product during its operation. Waste heat can also be generated by other components that may be provided in some embodiments. Some non-limiting examples of these other components that generate waste heat as a by-product of operation include amplifiers, integrated circuits, transformers, voltage regulators, hard disk drives, and resistors, among others.

At 320 of flow diagram 300, in one embodiment, the method provides a thermoelectric device that is thermally coupled with the processing component and configured for generating electricity from waste heat of the processing component. In one embodiment, this comprises providing thermoelectric device 120 which is coupled directly or indirectly (such as via heat transfer mechanism 122) with processing component (e.g., 110-1, 110-2, or other processing component). In some embodiments, the thermoelectric device may also be coupled one or more other components of the computing appliance that also produce waste heat.

At 330 of flow diagram 300, in one embodiment, the method provides a charge storage device that is electrically coupled with the thermoelectric device and configured to charge from the electricity generated by the thermoelectric device. This can comprise electrically coupling charge storage device 140 with thermoelectric device 120 and charging charge storage device 140 with some portion of the electricity generated by thermoelectric device 120. In one embodiment, this electrical coupling is accomplished with electrical bus 126. It is appreciated that one or more components 150 can be coupled with charge storage device 140 via electrical bus 126.

At 340 of flow diagram 300, in one embodiment, the method provides a real-time parasitic component of an electrical appliance. The real-time parasitic component is electrically coupled with a thermoelectric device and with a charge storage device. In one embodiment, this can comprise real-time parasitic component 157 that is electrically coupled with thermoelectric device 120 via electrical bus 126. It is appreciated that in some embodiments, a plurality of real-time parasitic components 157 may be similarly coupled with thermoelectric device 120 to receive all or part of their electricity needs from the electricity generated by thermoelectric device 120. The real-time parasitic component 157 receives all or a portion of real-time operating electricity for the real-time parasitic component 157 from thermoelectric device 120 and all or a portion of parasitic operating electricity for real-time parasitic component 157 from charge storage device 140. In one embodiment, surge electricity needs of real-time parasitic component 157 that are over and above the electricity provided by thermoelectric device 120 are provided by charge storage device 140. In one embodiment, real-time electricity needs over and above the surge capacity of charge storage device 140 and/or parasitic electricity needs over and above the capacity of charge storage device 140 default to being provided by the electricity grid (e.g., from wall socket connected electricity). Additionally, in some embodiments, one or more real-time components 153 and/or parasitic components 155 can be similarly electrically coupled with thermoelectric device 120.

At 350 of flow diagram 300, in one embodiment, the method provides a heat transfer mechanism that is thermally coupled with the thermoelectric device and also coupled with one or more heat generating components of the computing appliance. This can comprise providing heat transfer mechanism 122 in a fashion such that it is thermally coupled with thermoelectric device 120 and is also thermally coupled with one or more processors (e.g., 110-1, 110-2, and/or other processing component), one or more other heat generating components of the computing appliance, and/or some combination of one or more processors and other heat generating components. In this manner, heat generated from one or more heat generating components is transferred to thermoelectric device 120 and/or to other electricity generating means such as microturbine 135.

At 360 of flow diagram 300, in one embodiment, the method providing a heat sink thermally coupled with the thermoelectric device. In one embodiment, this comprises providing a heat sink 124 that is disposed on a surface of thermoelectric device 120 that not the surface of thermoelectric device 120 which is thermally coupled with a heat generating component 110.

At 370 of flow diagram 300, in one embodiment, the method provides a microturbine electrically coupled with the storage device. The microturbine is configured to generate additional electricity from waste heat radiated from the computing appliance as a by-product of the operation of the computing appliance. For example, in one embodiment, fluid movement induced by convection via the waste heat of one or more heat generating components is used to turn the microturbine or microturbines that are electrically coupled with the charge storage device. In one embodiment, this comprises charge storage device 140 (or similar charge storage) being additionally or alternatively electrically coupled with electricity generated by means such as microturbine 130 and/or microturbine 135. This electrical coupling is accomplished using electrical bus 126 or similar electrical bus. In one embodiment, the electricity generated by microturbine 130 and/or microturbine 135 is used in real-time to power a real-time component 153, a real-time parasitic component 157, and/or to provide electricity to a peripheral device 161 via a peripheral device attachment point 160. This electricity can be used separately from or in combination with electricity generated by thermoelectric device 120. Additionally, the electricity generated by microturbine 130 and/or microturbine 135 can be stored in charge storage device 140 for surge use or later use by a component 150 and/or by a peripheral device 161.

Example embodiments of the subject matter are thus described. Although various embodiments of the subject matter have been described in a language specific; to structural features and/or methodological acts, it is to be understood that the appended claims are not necessarily limited to the specific features or acts described above. Rather, the specific features and acts described above are disclosed as example forms of implementing the claims and their equivalents.

1. A system for deriving operating electricity for an electrical appliance from wasted heat of said electrical appliance, said system comprising:
an electrical appliance with a heat generating component, wherein said heat generating component generates heat as a by-product of other operation of said heat generating component;
a thermoelectric device thermally coupled with said heat generating component and configured to thermoelectrically generate electricity from waste heat of said heat generating component 110, said waste heat generated by said heat generating component during operation of said electrical appliance;
a charge storage device 140 electrically coupled with said thermoelectric device 420 and configured to store a portion of said electricity generated by said thermoelectric device; and
a real-time parasitic component of said electrical appliance said real-time parasitic component electrically coupled with said thermoelectric device and with said charge storage device, said real-time parasitic component configured to receive a portion of real-time operating electricity for said real-time parasitic component from said thermoelectric device and a portion of parasitic operating electricity for said real-time parasitic component; from said charge storage device.

2. The system as recited in claim 1, further comprising:
a real-time component electrically coupled with said thermoelectric device and configured to receive a portion of real-time operating electricity for said real-time component from said thermoelectric device; and
a parasitic component electrically coupled with said charge storage device 140 and configured to receive a portion of parasitic operating electricity for said real-time parasitic component from said charge storage device.

3. The system as recited in claim 1, farther comprising:
microturbine coupled with said electrical appliance and configured to generate additional electricity from fluid movement induced by convection via heat radiated from operation of said electrical appliance.

4. The system as recited in claim 2, further comprising:
a peripheral device attachment point electrically coupled with said charge storage device and configured for receiving electrical power from said charge storage device.

5. The system as recited in claim 1, further comprising:
a heat transfer mechanism, wherein said thermoelectric device is thermally coupled via said heat transfer mechanism with a plurality of heat generating components of said electrical appliance such that heat is transferred from said plurality of heat generating components to said thermoelectric device.

6. The system as recited in claim 1, wherein said real-time component comprises also consumes electrical power when said electrical appliance is in a powered down state.

7. A method of recycling waste heat of an electrical appliance into operating electricity for said electrical appliance, said method comprising:
capturing waste heat generated by a component of said electrical appliance;
recycling said captured wasted heat by using a thermoelectric device to generate electricity from said captured waste heat; and
providing said electricity for use by a real-time parasitic component of said electrical appliance.

8. The method as recited in claim 7, further comprising:
generating additional electricity with a microturbine coupled with said electrical appliance, said microturbine configured to generate said additional electricity from fluid movement induced by convection via heat radiated from operation of said electrical appliance.

9. The method as recited in claim 7, wherein said capturing waste heat generated by a component of said electrical appliance comprises:
capturing said wasted heat from said component with a heat transfer mechanism, said heat transfer mechanism thermally coupled with said component and at least one other heat generating component.

10. The method as recited in claim 7, wherein said providing said electricity for use by said electrical appliance comprises:
charging a charge storage device with said electricity; and
providing a portion of parasitic operating electricity for said real-time parasitic component from said charge storage device.

11. The method as recited in claim 7, wherein said providing said electricity for use by said electrical appliance comprises:
powering, at least in part, a real-time component of said electrical appliance with said electricity.

12. A method for providing a computing appliance, said method comprising:
providing a processing component;
providing a thermoelectric device thermally coupled with said processing component and configured for generating electricity from waste heat of said processing component;
providing a charge storage device electrically coupled with said thermoelectric device and configured to charge from said electricity generated by said thermoelectric device; and
providing a real-time parasitic component of said computing appliance, said real-time parasitic component electrically coupled with said thermoelectric device for receiving at least a portion of real-time operating electricity for said real-time parasitic component from said thermoelectric device and electrically coupled with said charge storage device for receiving at least a portion of parasitic operating electricity from said charge storage device.

13. The method as recited in claim 12, further comprising:
providing a heat transfer mechanism thermally coupled with said thermoelectric device and also coupled with a plurality of heat generating components of said computing appliance.

14. The method as recited in claim 12, further comprising:
providing a heat sink thermally coupled with said thermoelectric device.

15. The method as recited in claim 14, further comprising:
providing a microturbine electrically coupled with said storage device, said microturbine configured to generate additional electricity from fluid movement induced by convection via heat radiated from operation of said computing appliance.
